(19) United States
(12) Patent Application Publication
(10) Pub. No.: US 2025/0247946 A1
(43) Pub. Date: Jul. 31, 2025

(54) POWER BOARD

(71) Applicant: ZF Friedrichshafen AG, Friedrichshafen (DE)

(72) Inventors: Shaozhi Yuan, Shanghai (CN); Qing Xu, Shanghai (CN)

(73) Assignee: ZF Friedrichshafen AG, Friedrichshafen (DE)

(21) Appl. No.: 19/040,441

(22) Filed: Jan. 29, 2025

(30) Foreign Application Priority Data
Jan. 29, 2024 (CN) 202410124042.X

(51) Int. Cl. H05K 1/02; H05K 1/11

(52) U.S. Cl. CPC H05K 1/0206; H05K 1/111; H05K 1/115; H05K 2201/041; H05K 2201/09618; H05K 2201/09727; H05K 2201/10522

(57) ABSTRACT

A power board includes a plurality of power chips, a first prefabricated board, the plurality of power chips being embedded in the first prefabricated board, and a plurality of conductive pattern layers and a plurality of insulating layers, the plurality of conductive pattern layers and the plurality of insulating layers being alternately stacked above and/or below the first prefabricated board, wherein the plurality of power chips are electrically connected to the plurality of conductive pattern layers. A curvature of the power board of the present application can be adjusted by adjusting the position of the prefabricated board, and the power board has excellent heat dissipation performance.

### CROSS-REFERENCE TO RELATED APPLICATION

This application claims priority to Chinese Patent Application No. 202410124042.X, filed on Jan. 29, 2024, the entirety of which is hereby fully incorporated by reference herein.

### TECHNICAL FIELD

The present application relates mainly to the field of chip packaging, and in particular to a power board.

### BACKGROUND

Printed circuit board is abbreviated as PCB, also known as printed board, which is one of the important components of electronic products. The printed circuit board generally has a copper foil covering an insulating board, so it can also be called copper clad board. PCB can be divided into a single-sided printed board and a double-sided printed board. The single-sided printed board refers to a printed board having a conductive pattern on one side, and the double-sided printed board refers to a printed board having conductive patterns on two sides, which has a printed circuit formed, by means of printing and etching, on an insulating substrate with copper foils coated on two sides thereof, electrical interconnection between the two sides being implemented by means of metallized holes. The printed circuit board may be used to package power chips. There are many problems in packaging the power chips in the printed circuit board, for example, how to make the curvature of the power board meet the requirements, and how to ensure the heat dissipation performance of the power chips.

### SUMMARY

A technical problem to be solved by the present application is to provide a power board having the technical effects of adjustable curvature and excellent heat dissipation performance.

In order to solve the technical problem described above, the present application provides a power board, including: a plurality of power chips; a first prefabricated board, the plurality of power chips being embedded in the first prefabricated board; a plurality of conductive pattern layers and a plurality of insulating layers, the plurality of conductive pattern layers and the plurality of insulating layers being alternately stacked above and/or below the first prefabricated board, wherein the plurality of power chips are electrically connected to the plurality of conductive pattern layers.

In an embodiment of the present application, the plurality of power chips are embedded in a substrate, and the substrate is embedded in the first prefabricated board.

In an embodiment of the present application, the power board further includes a second prefabricated board, the second prefabricated board being located above or below the first prefabricated board, wherein at least one of the conductive pattern layers and/or the insulating layers is located between the first prefabricated board and the second prefabricated board.

In an embodiment of the present application, the first prefabricated board is located at a bottom layer of the power board and the second prefabricated board is located at a top layer of the power board, wherein the plurality of conductive pattern layers and the plurality of insulating layers are located between the first prefabricated board and the second prefabricated board.

In an embodiment of the present application, the first prefabricated board is located at a bottom layer of the power board, and the second prefabricated board is spaced from the first prefabricated board by a preset distance.

In an embodiment of the present application, the second prefabricated board is located at a bottom layer of the power board, and the first prefabricated board is located above the second prefabricated board.

In an embodiment of the present application, the power board further includes a heat dissipation block, the heat dissipation block being embedded in the second prefabricated board, and a top surface of the heat dissipation block being in contact with a bottom surface of a substrate, wherein the plurality of power chips are embedded in the substrate, and the substrate is embedded in the first prefabricated board.

In an embodiment of the present application, some of the conductive pattern layers and some of the insulating layers are located above the first prefabricated board, and the remaining conductive pattern layers and the remaining insulating layers are located below the first prefabricated board.

In an embodiment of the present application, the power board further includes a plurality of heat dissipation columns, the plurality of heat dissipation columns being located below the first prefabricated board, top surfaces of the plurality of heat dissipation columns being in contact with a substrate, and bottom surfaces of the plurality of heat dissipation columns being in contact with a conductive pattern layer located below the bottom surfaces, wherein the plurality of power chips are embedded in the substrate, and the substrate is embedded in the first prefabricated board.

In an embodiment of the present application, the prefabricated board includes at least two preset conductive pattern layers and at least one connection layer, wherein each connection layer is located between adjacent preset conductive pattern layers.

The curvature of the power board of the present application can be adjusted by adjusting the position of the prefabricated board, and the power board has excellent heat dissipation performance.

The accompanying drawings are included to provide a further understanding of the present application and are incorporated into and constitute a part of the present application, show embodiments of the present application, and serve to, together with the description, explain the principles of the present application.

### BRIEF DESCRIPTION OF THE DRAWINGS

FIG. 1 is a schematic cross-sectional view of a power board according to an embodiment of the present application;

FIG. 2 is a schematic cross-sectional view of the power board of FIG. 1 taken along line A-A;

FIG. 3 is a schematic cross-sectional view of a power board according to another embodiment of the present application;

FIG. 4 is a schematic cross-sectional view of a power board according to an embodiment of the present application;

FIG. 5 is a schematic cross-sectional view of a power board according to another embodiment of the present application; and

FIG. 6 is a schematic cross-sectional view of a power board according to an embodiment of the present application.

### DETAILED DESCRIPTION

To describe technical solutions of embodiments of the present application more clearly, the accompanying drawings required for describing the embodiments will be briefly described below. Obviously, the accompanying drawings described below show merely some of the examples or embodiments of the present application, and those of ordinary skill in the art would also have applied the present application to other similar scenarios according to these accompanying drawings without involving any creative effort. Unless obvious from the language context or otherwise illustrated, the same reference numerals in the drawings represent the same structure or operation.

As shown in the present application and the claims, unless the context expressly indicates otherwise, the words “a”, “an”, “said”, and/or “the” do not specifically refer to the singular, but may also include the plural. Generally, the terms “include” and “comprise” only suggest that the expressly identified steps and elements are included, but these steps and elements do not constitute an exclusive list, and the method or device may further include other steps or elements.

Unless otherwise indicated specifically, the relative arrangement, numerical expressions and values of the components and steps set forth in these embodiments do not limit the scope of the present application. In addition, it should be understood that, for ease of description, the dimensions of the various parts shown in the accompanying drawings are not drawn according to the actual proportional relationship. Techniques, methods and devices known to those of ordinary skill in the relevant field may not be discussed in detail, but where appropriate, the techniques, methods and devices should be considered as part of the authorized description. In all of the examples shown and discussed here, any specific value should be construed as merely exemplary but not limiting. Therefore, other examples of exemplary embodiments may have different values. It should be noted that similar reference signs and letters refer to similar items in the following drawings. Therefore, once an item is defined in one of the drawings, it is not necessary to further discuss the item in subsequent drawings.

In the description of the present application, it should be understood that orientations or position relationships indicated by orientation terms such as “front, rear, up, down, left, and right”, “transverse, vertical, perpendicular, and horizontal”, and “top and bottom” are generally based on orientations or position relationships shown in the drawings and are merely for ease of description of the present application and simplification of the description, rather than indicating and implying that the apparatuses or elements referred to must have a specific orientation or be constructed and operated in a specific orientation if there is no explanation to the contrary, and therefore cannot be construed as limiting the scope of protection of the present application. The orientation terms “interior and exterior” refer to inside and outside relative to a contour of each component itself.

For ease of description, spatial relative terms such as “over . . . ”, “above . . . ”, “on an upper surface of . . . ”, and “on . . . ” may be used here to describe a spatial position relationship between one device or feature and another device or feature as shown in the figures. It should be understood that the spatial relative terms are intended to encompass different orientations of the device in use or operation, in addition to the orientation of the device described in the figure. For example, if devices in the figure are inverted, the device described as “above” or “over” another device or structure will later be positioned as “below” or “under” another device or structure. Therefore, the exemplary term “above . . . ” may include both “above . . . ” and “below . . . ” orientations. The device may also be positioned in other different ways (rotated by 90 degrees or in other orientations), and the spatial relative descriptions used here are interpreted accordingly.

Furthermore, it should be noted that, the use of terms such as “first” and “second” to define parts is merely for ease of facilitating differentiation of the corresponding parts. If not otherwise stated, the above terms have no special meanings and thus cannot be construed as limiting the scope of protection of the present application. Furthermore, although the terms used in the present application are selected from well-known common terms, some of the terms mentioned in the description of the present application may have been selected by the applicant according to his or her determination, and the detailed meaning thereof is described in the relevant section described herein. Furthermore, the present application must be understood, not simply by the actual terms used but also by the meanings encompassed by each term.

A power board of the present application will be described below with reference to embodiments.

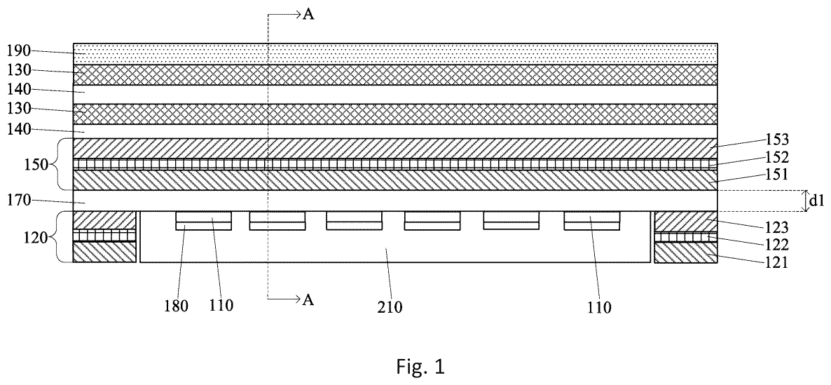

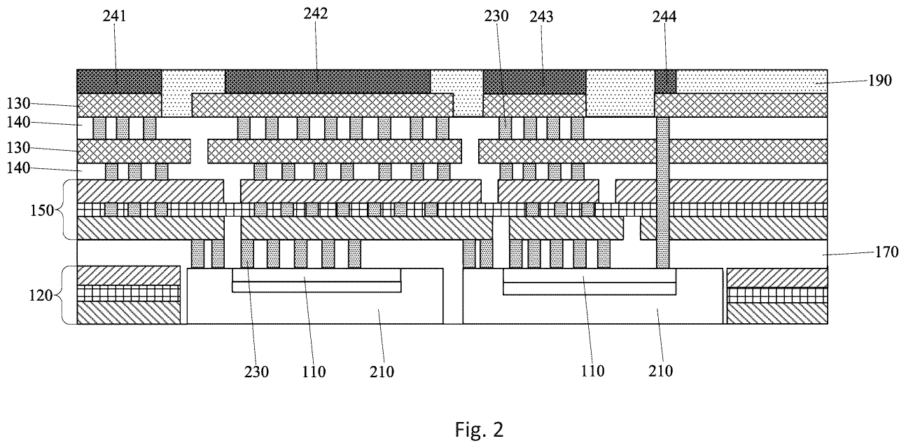

FIG. 1 is a schematic cross-sectional view of a power board according to an embodiment, and FIG. 2 is a schematic cross-sectional view of the power board of FIG. 1 taken along line A-A. Referring to FIGS. 1 and 2, the power board includes 12 power chips 110, a first prefabricated board 120, a plurality of conductive pattern layer 130 and a plurality of insulating layer 140. The 12 power chips 110 are electrically connected to the plurality of conductive pattern layers 130.

Specifically, the power board includes two rows of power chips 110, each row including six power chips 110. The arrangement and number of power chips 110 are not limited to the embodiment in FIGS. 1 and 2, and may be set according to the actual situation. The power chips 110 may be silicon carbide substrate power chips, silicon substrate power chips, or silicon carbide-silicon hybrid substrate power chips.

The power chips 110 are embedded in the substrate 210. The substrate 210 has a groove for receiving the power chips 110, and the power chips 110 may be connected to the substrate 210 by means of a solder 180 located between the power chips 110 and a bottom surface of the groove. The power chips 110 may be electrically connected to the substrate 210. The substrate 210 is embedded in the first prefabricated board 120. The first prefabricated board 120 has a cavity for receiving the substrate 210, and the substrate 210 may be connected to a side wall of the cavity by means of an insulating adhesive. The material of the substrate 210 may include metallic copper.

In an embodiment, the first prefabricated board 120 includes a first preset conductive pattern layer 121, a first connection layer 122, and a second preset conductive pattern layer 123 stacked in sequence. The first preset conductive pattern layer 121 and the second preset conductive pattern layer 123 are electrically conductive, and the first preset conductive pattern layer 121 and the second preset conductive pattern layer 123 each may be a copper foil having a specific pattern. The first connection layer 122 is insulated, and the first connection layer 122 connects the first preset conductive pattern layer 121 to the second preset conductive pattern layer 123. The first connection layer 122 may be made of glass fiber. The number of preset conductive pattern layers in the first prefabricated board 120 is not limited to 2. For example, the number of preset conductive pattern layers may be 4, and one first connection layer is provided between two adjacent preset conductive pattern layers. The thickness of the first prefabricated board 120 can be adjusted by changing the number of preset conductive pattern layers.

The plurality of conductive pattern layers 130 and the plurality of insulating layers 140 are alternately stacked above the first prefabricated board 120. The conductive pattern layer 130 is electrically conductive, and the conductive pattern layer 130 may be a copper foil having a specific pattern. The insulating layer 140, which is insulated, may be used to connect two adjacent conductive pattern layers 130. In some embodiments, the insulating layer 140 may include a solid adhesive. The plurality of conductive pattern layers 130 and the plurality of insulating layers 140 may be alternately stacked above the first prefabricated board 120 using a lamination process. The number of conductive pattern layers 130 and the number of insulating layers 140 are not limited to those shown in FIGS. 1 and 2. For example, the number of conductive pattern layers 130 may be 4, 5 or 6.

In the lamination process, the number of laminations is positively correlated with the number of conductive pattern layers 130. Since the first prefabricated board 120 is already prepared prior to the lamination process, the use of the first prefabricated board 120 can reduce the number of laminations, thereby improving the production efficiency of the power board.

With reference to FIGS. 1 and 2, the power chips 110 may be point-connected to pads located on a surface of the power board by means of metallic holes 230 located between the conductive pattern layers 130. The pads may include a first pad 241, a second pad 242, a third pad 243, and a fourth pad 244 connection. The first pad 241 may be electrically connected to a drain of a left power chip 110, the second pad 242 may be electrically connected to a source of the left power chip 110 and a drain of a right power chip 110, the third pad 243 may be electrically connected to the source of the right left power chip 110, and the fourth pad 244 may be electrically connected to gates of the power chips 110.

In an embodiment, the power board further includes a protective layer 190. The protective layer 190 covers the top conductive pattern layer 130. The protective layer 190 includes a liquid solder mask. The protective layer 190 can be used to protect the power board from erosion.

In an embodiment, the power board further includes a second prefabricated board 150. The second prefabricated board 150 includes a third preset conductive pattern layer 151, a second connection layer 152 and a fourth preset conductive pattern layer 153 stacked in sequence. The third preset conductive pattern layer 151 and the fourth preset conductive pattern layer 153 are electrically conductive, and the third preset conductive pattern layer 151 and the fourth preset conductive pattern layer 153 each may be a copper foil having a specific pattern. The second connection layer 152 is insulated, and the second connection layer 152 may be made of glass fiber. The second connection layer 152 connects the third preset conductive pattern layer 151 to the fourth preset conductive pattern layer 153. For other descriptions of the second prefabricated board 150, reference may be made to the above descriptions of the first prefabricated board 120, which will not be elaborated herein.

The second prefabricated board 150 may be located above the first prefabricated board 120, the two being connected to each other via a third connection layer 170. The third connection layer 170 is insulated. The use of both the first prefabricated board 120 and the second prefabricated board 150 can further reduce the number of laminations. In addition, the second prefabricated board 150 can adjust the curvature of the power board.

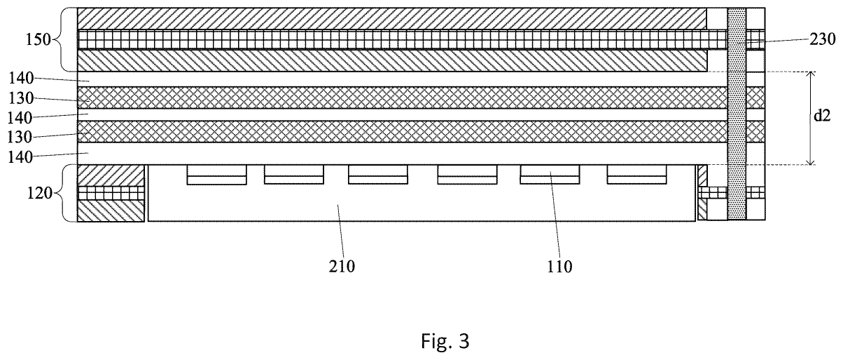

Reference is made to FIGS. 1 and 3. In FIG. 1, the first prefabricated board 120 is located at a bottom layer of the power board, the second prefabricated board 150 is located above the first prefabricated board 120, and the second prefabricated board 150 is spaced from the first prefabricated board 120 by a first preset distance d1. In FIG. 3, the first prefabricated board 120 is located at the bottom layer of the power board, the second prefabricated board 150 is located at a top layer of the power board, and the plurality of conductive pattern layers 130 and the plurality of insulating layers 140 are located between the first prefabricated board 120 and the second prefabricated board 150. Disposing the first prefabricated board 120 at the bottom layer of the power board can facilitate the direct connection of a heat sink on a back surface of the substrate 210, so that a good heat dissipation effect can be achieved. The first prefabricated board 120 at the bottom layer will cause the power board to bend, and the second prefabricated board 150 located above the first prefabricated board 120 can balance the bending caused by the first prefabricated board 120.

The second prefabricated board 150 is spaced from the first prefabricated board 120 by a second preset distance d2. The second preset distance d2 is greater than the first preset distance d1. By adjusting the values of the preset distances, the stress applied to the power board by the first prefabricated board 120 and the second prefabricated board 150 can be adjusted, thereby adjusting the curvature of the power board. For example, in FIG. 3, the first prefabricated board 120 and the second prefabricated board 150 are symmetrical about an insulating layer 140 located at the second layer, so that the stresses applied by the two on the power board can cancel each other, thereby reducing the curvature of the power board.

Referring to FIG. 3, a process of stacking the layers of the power board may include the steps of: stacking the second prefabricated board 150, an insulating layer 140 located below the second prefabricated board 150, and a conductive pattern layer 130 located below the second prefabricated board 150, the stacked structure described above being referred to as a first stacked structure for convenience of description; stacking the first prefabricated board 120, an insulating layer 140 located above the first prefabricated board 120, and a conductive pattern layer 130 located above the first prefabricated board 120, the stacked structure described above being referred to as a second stacked structure for convenience of description; and stacking the first stacked structure, the second stacked structure, and an insulating layer 140 located between the first stacked structure and the second stacked structure. The metallic holes 230 may electrically connected the first stacked structure to the second stacked structure. In contrast to the technical solution of stacking layers of a power board layer by layer, the preparation of the power board by the above steps can reduce the diameter of the metallic holes 230 while ensuring that the conductive properties of the metallic holes 230 meet the requirements. The power board includes a plurality of metallic holes 230, and the reduced diameter of the metallic holes 230 facilitates the increase of the density of the metallic holes 230 per unit area, thereby improving the current carrying performance of the power board.

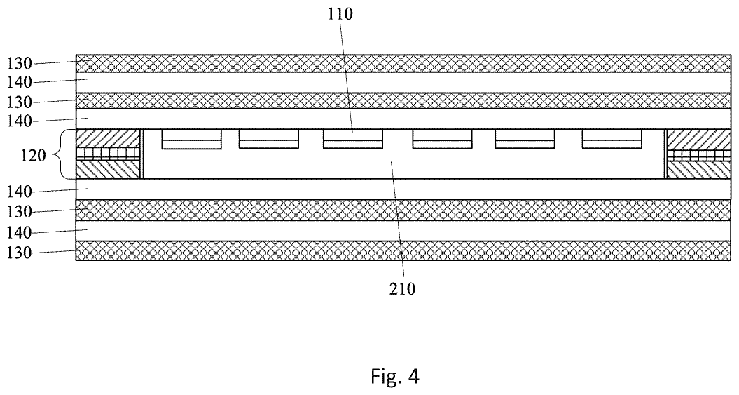

FIG. 4 is a schematic cross-sectional view of a power board according to an embodiment. In contrast to FIG. 1, the first prefabricated board 120 in FIG. 4 is located in the middle of the power board. Two conductive pattern layers 130 and two insulating layers 140 are stacked above the first prefabricated board 120, and two conductive pattern layers 130 and two insulating layers 140 are stacked below the first prefabricated board 120. In other words, the conductive pattern layers 130 and the insulating layers 140 located above the first prefabricated board 120 are symmetrical about the first prefabricated board 120 with the conductive pattern layers 130 and the insulating layers 140 located below the first prefabricated board. Disposing the first prefabricated board 120 in the middle of the power board helps to reduce the curvature of the power board, and also helps to dissipate heat from the power board, thereby achieving a balance between heat dissipation and curvature. In some embodiments, the conductive pattern layers 130 and the insulating layers 140 above the first prefabricated board 120 may be removed, leaving the conductive pattern layers 130 and the insulating layers 140 below the first prefabricated board 120.

In other embodiments, some of the conductive pattern layers 130 and some of the insulating layers 140 are located above the first prefabricated board 120, and the remaining conductive pattern layers 130 and the remaining insulating layers 140 are located below the first prefabricated board 120. For example, there are a total of six conductive pattern layers 130, where four conductive pattern layers 130 are located above the first prefabricated board 120 and two conductive pattern layers 130 are located below the first prefabricated board 120.

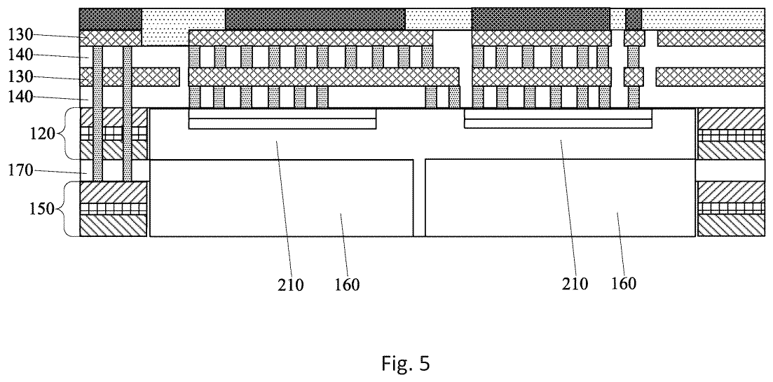

FIG. 5 is a schematic cross-sectional view of a power board according to another embodiment. Referring to FIG. 5, the second prefabricated board 150 is located at a bottom layer of the power board, and the first prefabricated board 120 is located above the second prefabricated board 150. A third connection layer 170 is located between the first prefabricated board 120 and the second prefabricated board 150, and the third connection layer 170 may be used to connect the first prefabricated board 120 to the second prefabricated board 150.

In an embodiment, the power board further includes a heat dissipation block 160. The heat dissipation block 160 is embedded in the second prefabricated board 150, and a top surface of the heat dissipation block 160 is in contact with a bottom surface of the substrate 210. The heat dissipation block 160 may be used to dissipate heat from the substrate 210, thereby improving the heat dissipation effect of the power board. The material of the heat dissipation block 160 may include metallic copper.

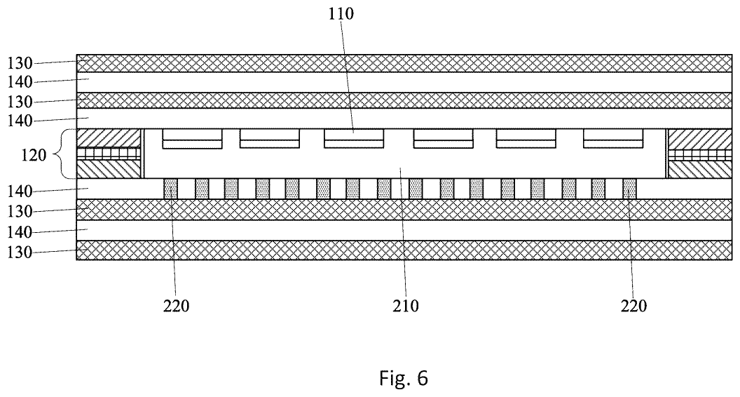

FIG. 6 is a schematic cross-sectional view of a power board according to an embodiment. Referring to FIG. 6, the power board may include a plurality of heat dissipation columns 220. The heat dissipation columns 220 are located between the first prefabricated board 120 and an adjacent conductive pattern layer 130 located below the first prefabricated board 120, top surfaces and bottom surfaces of the heat dissipation columns 220 are in contact with the substrate 210 and the conductive pattern layer 130, respectively, and the heat dissipation columns 220 can be used to transfer heat from the power chip to the conductive pattern layer 130. The material of the heat dissipation column 220 may include metallic copper.

The basic concepts have been described above. Obviously, for those skilled in the art, the above disclosure of the present application is merely used as an example and does not constitute a limitation on the present application. Although not explicitly stated herein, various modifications, improvements and amendments may be made to the present application by those skilled in the art. Such modifications, improvements and amendments are suggested in the present application, and therefore, such modifications, improvements and amendments still fall within the spirit and scope of the exemplary embodiments of the present application.

Meanwhile, the present application uses specific terms to describe the embodiments of the present application. For example, “one embodiment”, “an embodiment”, and/or “some embodiments” mean a feature, structure, or characteristic associated with at least one embodiment of the present application. Therefore, it should be emphasized and noted that “an embodiment” or “one embodiment” or “an alternative embodiment” mentioned twice or more in different positions in the description does not necessarily refer to the same embodiment. Furthermore, some features, structures, or characteristics of the one or more embodiments of the present application may be combined appropriately.

Similarly, it should be noted that to simplify the expressions in the disclosure of the present application to assist in the understanding of one or more embodiments of the present application, a plurality of features may sometimes be incorporated into an embodiment and accompanying drawing, or a description thereof in the foregoing description of the embodiments of the present application. However, such a method of disclosure does not mean that the subject of the present application requires more features than those mentioned in the claims. In fact, the features of the embodiments are less than all the features of a single embodiment disclosed above.

Figures for describing the quantity of components and attributes are used in some embodiments. It should be understood that such figures for use in the description of the embodiments are modified with modifiers “about,” “approximately,” or “substantially” in some examples. Unless otherwise specified, “about,” “approximately,” or “substantially” indicates that a variation of ±20% is allowed for the figures. Accordingly, in some embodiments, numerical parameters used in the description and the claims are all approximations, which can change depending on desired characteristics of individual embodiments. In some embodiments, for the numerical parameters, a specified number of valid digits should be considered, and a general bit retention method is used. Although numerical fields and parameters used to confirm the breadth of their ranges in some embodiments of the present application are approximations, such values are set to the extent practicable as precisely as possible in specific embodiments.

While the present application has been described with reference to the specific embodiments at hand, those of ordinary skill in the art would realize that the above embodiments are merely used to illustrate the present application, and various equivalent changes or substitutions can also be made without departing from the spirit of the present application. Therefore, any change and variation made to the above embodiments within the substantial spirit and scope of the present application shall fall within the scope of the claims of present application.

### LIST OF REFERENCE SIGNS

Power chip 110
First prefabricated board 120
First preset conductive pattern layer 121
First connection layer 122
Second preset conductive pattern layer 123
Conductive pattern layer 130
Insulating layer 140
Second prefabricated board 150
Third preset conductive pattern layer 151
Second connection layer 152
Fourth preset conductive pattern layer 153
Heat dissipation block 160
Third connection layer 170
Solder 180
Protective layer 190
Substrate 210
Heat dissipation column 220
Metallic hole 230
First pad 241
Second pad 242
Third pad 243
Fourth pad 244

1. A power board, comprising:
a plurality of power chips;
a first prefabricated board, the plurality of power chips being embedded in the first prefabricated board; and
a plurality of conductive pattern layers and a plurality of insulating layers, the plurality of conductive pattern layers and the plurality of insulating layers being alternately stacked above and/or below the first prefabricated board, wherein the plurality of power chips are electrically connected to the plurality of conductive pattern layers.

2. The power board of claim 1, wherein the plurality of power chips are embedded in a substrate, and the substrate is embedded in the first prefabricated board.

3. The power board of claim 1, further comprising a second prefabricated board, the second prefabricated board being located above or below the first prefabricated board, wherein at least one of the conductive pattern layers and/or the insulating layers is located between the first prefabricated board and the second prefabricated board.

4. The power board of claim 3, wherein the first prefabricated board is located at a bottom layer of the power board and the second prefabricated board is located at a top layer of the power board, wherein the plurality of conductive pattern layers and the plurality of insulating layers are located between the first prefabricated board and the second prefabricated board.

5. The power board of claim 3, wherein the first prefabricated board is located at a bottom layer of the power board, and the second prefabricated board is spaced from the first prefabricated board by a preset distance.

6. The power board of claim 3, wherein the second prefabricated board is located at a bottom layer of the power board, and the first prefabricated board is located above the second prefabricated board.

7. The power board of claim 6, further comprising a heat dissipation block, the heat dissipation block being embedded in the second prefabricated board, and a top surface of the heat dissipation block being in contact with a bottom surface of a substrate, wherein the plurality of power chips are embedded in the substrate, and the substrate is embedded in the first prefabricated board.

8. The power board of claim 1, wherein at least one of the conductive pattern layers and at least one of the insulating layers are located above the first prefabricated board, and remaining conductive pattern layers and remaining insulating layers are located below the first prefabricated board.

9. The power board of claim 8, further comprising a plurality of heat dissipation columns, the plurality of heat dissipation columns being located below the first prefabricated board, top surfaces of the plurality of heat dissipation columns being in contact with a substrate, and bottom surfaces of the plurality of heat dissipation columns being in contact with a conductive pattern layer located below the bottom surfaces, wherein the plurality of power chips is embedded in the substrate, and the substrate is embedded in the first prefabricated board.

10. The power board of claim 1, wherein the first prefabricated board comprises at least two preset conductive pattern layers and at least one connection layer, wherein each connection layer is located between adjacent preset conductive pattern layers.
